(19) United States
(12) Patent Application Publication
(10) Pub. No.: US 2019/0259618 A1
(43) Pub. Date: Aug. 22, 2019

(54) PROCESS FOR FORMING A LAYER OF A WORK FUNCTION METAL FOR A MOSFET GATE HAVING A UNIAXIAL GRAIN ORIENTATION

(71) Applicant: STMicroelectronics (Crolles 2) SAS, Crolles (FR)

(72) Inventors: Florian Domengie, Crolles (FR); Pushpendra Kumar, Grenoble (FR)

(73) Assignee: STMicroelectronics (Crolles 2) SAS, Crolles (FR)

(21) Appl. No.: 15/898,851

(22) Filed: Feb. 19, 2018

(51) Int. Cl. H01L 21/28; H01L 29/66; H01L 29/78; H01L 29/49

(52) U.S. Cl. CPC H01L 21/28061; H01L 29/6656; H01L 29/7833; H01L 29/4966; H01L 21/28088; H01L 29/6659; H01L 29/4941; H01L 21/28079; H01L 29/66545

(57) ABSTRACT

Local variability of the grain size of work function metal, as well as its crystal orientation, induces a variable work function and local variability of transistor threshold voltage. The metal nitride for the work function metal of the transistor gate is deposited using a radio frequency physical vapor deposition with process parameters selected so as to produce grains of material exhibiting a uniaxial grain orientation. The uniaxial grain structure for the metal nitride work function metal layer (such as with TiN) reduces local variability in threshold voltage.

### FIELD OF THE INVENTION

The present disclosure generally relates to integrated circuit transistors and, in particular, to a metal oxide semiconductor field effect transistor (MOSFET) device having a metal gate electrode with a work function (for example, titanium nitride (TiN)) material layer having a uniaxial grain orientation.

### BACKGROUND

Those skilled in the art are familiar with the structure and operation of metal oxide semiconductor field effect transistor (MOSFET) devices. Such devices include source, drain and channel regions formed in a semiconductor substrate as well as a gate formed over the channel region. The gate includes a gate oxide layer and a conductive gate stack insulated from the channel region by the gate oxide layer. The conductive gate stack may, for example, include a work function layer of a metal nitride (for example, titanium nitride TiN) that is located physically adjacent to the gate oxide and one or more other metal layers and/or semiconductor layers over the metal nitride layer.

It is often important for two or more MOSFET devices of an integrated circuit to be designed identically, in an identical environment, and operated identically. However, two identically designed MOSFET devices within an integrated circuit may operate differently; such as by having slightly different threshold voltages (Vt). Indeed, as the sizes (width and/or length) of the designed transistors decreases, experimentation has shown that the local variability of threshold voltage between identical transistors increases for dimensions above 1 μm (for length) or 1 μm² (for surface area=length×width). This can be a problem when correct circuit operation relies on the use of matched transistors.

It is also recognized by those skilled in the art that the work function (WF) of the metal gate has a direct effect on threshold voltage. This WF is known to be dependent on grain orientation of the selected WF material. Taking TiN material as an example, a crystallographic grain orientation of <200> has a WF of 4.6 eV while a crystallographic grain orientation of <111> has a WF of 4.4 eV. Conventional semiconductor fabrication processes for the deposition of a TiN layer in connection with the formation of the MOSFET metal gate typically produce TiN material which exhibits inconsistent grain orientation characteristics from transistor to transistor, and as a result there are differences in work function with a corresponding variability in threshold voltage from transistor to transistor.

A solution to the concern with threshold voltage variability is to reduce WF material variation among otherwise identically designed transistor devices. For example, a semiconductor material deposition process which utilizes a long duration and high temperature to produce the metal gate WF material can achieve large grain size of a single orientation. Conversely, a semiconductor material deposition process which utilizes a short duration and low temperature to produce the metal gate WF material can produce no grain growth, with a large number of small grains yielding a negligible WF variation. In an ideal case, an amorphous metal gate is preferred.

However, neither of these known processes is satisfactory. The long duration and high temperature metal gate WF material deposition process induces an adverse effect of Nitrogen desorption which leads to device decentering and device reliability degradation. The short duration and low temperature metal gate WF material deposition process requires a corresponding increase in DC/RF power that can cause damage to the high-K dielectric material for the gate oxide layer.

There is accordingly a need in the art for a metal gate WF material deposition process that can consistently produce metal gate WF material exhibiting a uniaxial grain orientation without incurring the drawbacks of device decentering, device reliability degradation and gate oxide damage that are associated with the known prior art processes.

### SUMMARY

In an embodiment, a method comprises: depositing a gate oxide layer over a substrate; depositing a work function metal nitride layer over the gate oxide layer; depositing a gate electrode layer over the work function metal nitride layer; wherein depositing the work function metal nitride layer comprises using a deposition process that produces the work function metal nitride layer exhibiting a uniaxial grain orientation.

In an embodiment, a method comprises: depositing a gate oxide layer over a substrate; depositing a work function metal nitride layer over the gate oxide layer; depositing a gate electrode layer over the work function metal nitride layer; wherein depositing the work function metal nitride layer comprises using a deposition process having a deposition pressure less than or equal to 1.6 mTorr that produces the work function metal nitride layer where greater than 95% of the metal nitride grains exhibit a <200> grain orientation.

In an embodiment, a method comprises: depositing a gate oxide layer over a substrate; depositing a work function metal nitride layer over the gate oxide layer; depositing a gate electrode layer over the work function metal nitride layer; wherein depositing the work function metal nitride layer comprises using a deposition process having a deposition pressure greater than or equal to 15 mTorr that produces the work function metal nitride layer where greater than 95% of the metal nitride grains exhibit a <111> grain orientation.

In an embodiment, an integrated circuit comprises: a substrate; a gate oxide layer deposited over the substrate; a work function metal nitride layer deposited over the gate oxide layer; a gate electrode layer deposited over the work function metal nitride layer; wherein greater than 95% of metal nitride grains of the work function metal nitride layer exhibit a <200> grain orientation.

In an embodiment, an integrated circuit comprises: a substrate; a gate oxide layer deposited over the substrate; a work function metal nitride layer deposited over the gate oxide layer; a gate electrode layer deposited over the work function metal nitride layer; wherein greater than 95% of metal nitride grains of the work function metal nitride layer exhibit a <111> grain orientation.

The foregoing and other features and advantages of the present disclosure will become further apparent from the following detailed description of the embodiments, read in conjunction with the accompanying drawings. The detailed description and drawings are merely illustrative of the disclosure, rather than limiting the scope of the invention as defined by the appended claims and equivalents thereof.

### BRIEF DESCRIPTION OF DRAWINGS

Embodiments are illustrated by way of example in the accompanying figures not necessarily drawn to scale, in which like numbers indicate similar parts, and in which:

FIG. 1 is process flow diagram for producing a transistor having an equiaxed grain orientation titanium nitride work function layer;

FIG. 2 is a cross sectional illustration of a deposition process device;

FIGS. 3A and 3B are cross-sectional images of a transistor gate region showing an equiaxed a titanium nitride work function layer;

FIG. 4 is process flow diagram for producing a transistor having a uniaxial grain orientation titanium nitride work function layer; and

FIGS. 5-7 are graphs showing the effects of varying process parameters for the production of a metal nitride exhibiting a uniaxial grain orientation.

### DETAILED DESCRIPTION

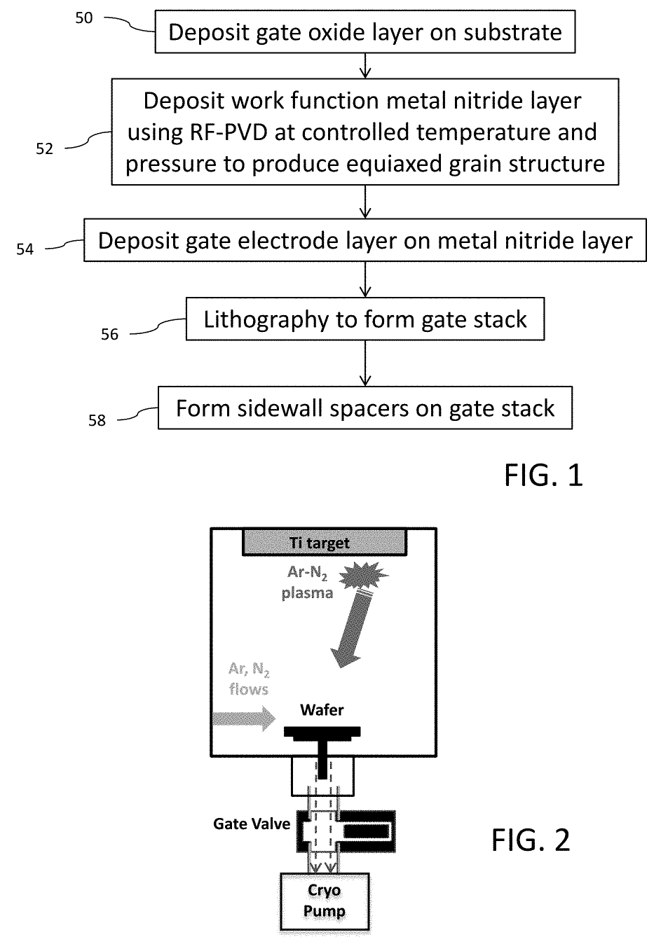

Reference is now made to FIG. 1 showing a process flow diagram for the formation of a transistor gate region in accordance with the teachings of U.S. Pat. No. 9,691,871 (incorporated herein by reference).

In step 50, a deposition of a gate oxide layer is made on a semiconductor substrate. The gate oxide may be deposited using a chemical vapor deposition (CVD) or atomic layer deposition (ALD) process. Such process usually requires an organometallic of halide precursor, and an oxidant reactant for the silicon oxide or metal oxide deposition. The process can also eventually include an additional reactant for a nitrogen source. Then usually a nitridation is performed to enrich the film in nitrogen, and a post nitridation anneal is carried out to fix nitrogen inside the film. The gate oxide may, for example, comprise a high-k dielectric material such as HfSiON or HfON. The gate oxide may, for example, have a thickness of 2 nm. The semiconductor substrate may, for example, comprise a bulk substrate, a silicon on insulator (SOI) substrate, a fin structure of the type commonly used in finFET devices, or any other suitable semiconductor structure containing source, drain and channel regions of a transistor. In high-k dielectrics, some nitrogen can eventually be added to change the dielectric constant and then tune the Capacitance Equivalent Thickness (CET). Nitrogen also has a beneficial impact on current leakage inside the gate oxide, and thus on threshold voltage and device consumption.

In step 52, a deposition of a work function metal nitride layer is made on the gate oxide layer. The work function metal nitride layer may, for example, comprise a titanium nitride (TiN) material. The deposition is made using a physical vapor deposition (PVD) process in radio frequency mode (RF-PVD). For a Gate-First integration scheme, where the work function metal nitride is deposited in planar mode and where highly uniform and continuous thin films are desirable (since work function metal thickness modulates threshold voltage of the MOSFET), PVD or RF-PVD deposition of the work function metal nitride is performed at relatively lower pressure, typically 2 to 5 mTorr. U.S. Pat. No. 9,691,871 proposes a modification of the standard commercial RF-PVD chamber to include a ‘mid-position gate valve’ (a gate valve between the chamber and its cryopump which has an additional, adjustable mid-opening position, in addition to the usual fully-open and fully-close positions) as shown in FIG. 2. This allows the process technician to throttle the cryopump and to achieve higher process pressure without using too high gas flow conditions and without decreasing the cryopump pumping capacity. As a result, the RF-PVD with controlled temperature and a relatively higher pressure will produce an equiaxed TiN film layer.

The following table provides an example of the process parameters used in RF-PVD for step 52 (where “Test” designates a point of reference only):

| | | |
|---|---|---|
| Deposition Parameter | Test | Ranges |

| | | | |
|---|---|---|---|
| Power DC (W) | 700 | 300 | 1000 |
| Power RF (W) | 600 | 100 | 1000 |
| Argon flow (sccm) | 20 | 5 | 50 |
| Nitrogen flow (sccm) | 45 | 15 | 100 |
| Pressure during deposition (mTorr) | 10 | 7 | 50 |
| Temperature (° C.) | 20 | −10 | 100 |

First, the wafer must be degased in a dedicated chamber at a temperature no more 200° C. and for a duration preferably no more than 30 seconds to remove moisture. Then the wafer is introduced inside the RF-PVD chamber. This chamber must be equipped with a pedestal set at the appropriate temperature, and hardware to clamp the wafer on the chuck. A gas vector at the backside of the wafer must also be used for good heat exchange. After wafer clamping (for example 1 second), temperature and process pressure stabilization (for example, 7.5 mTorr during 60 seconds, using Ar 100 sccm and nitrogen 50 sccm), the plasma is turned on with only RF power (for example, 1 second using RF 300 W). Then, after increasing RF power (for example, to 600 W), DC power is turned on during the appropriate time to reach the desired film thickness (for example, DC 700 W during 60 to 100 seconds). During this deposition, Ar flow is set to 20 sccm and nitrogen flow is set to 45 sccm to achieve a pressure of, for example, 10 mTorr. After that, DC power is turned off first (for example, during 0.5 second), and then finally RF power. At the end, the chamber is pumped down (for example, during at least 10 seconds).

Importantly, the RF-PVD process as described above is performed at a low enough temperature to ensure that the nitrogen added to the gate oxide layer for adjusting the centering of the transistor device is not desorbed.

In step 54, a deposition of a gate electrode layer is made on the metal nitride layer. The gate electrode may be deposited using a CVD process. For example, polysilicon is deposited inside a furnace at 600° C. using a silane precursor. The gate electrode may, for example, comprise a polysilicon material or a metal material (such as aluminum, tungsten, copper, etc.). The gate electrode layer may, for example, have a thickness of 50 nm.

In step 56, conventional lithographic processing techniques are used to pattern the gate electrode layer and the work function metal nitride layer to form a gate stack insulated from the substrate by the gate oxide layer.

In step 58, sidewall spacers are formed on at least the side surfaces of the gate stack.

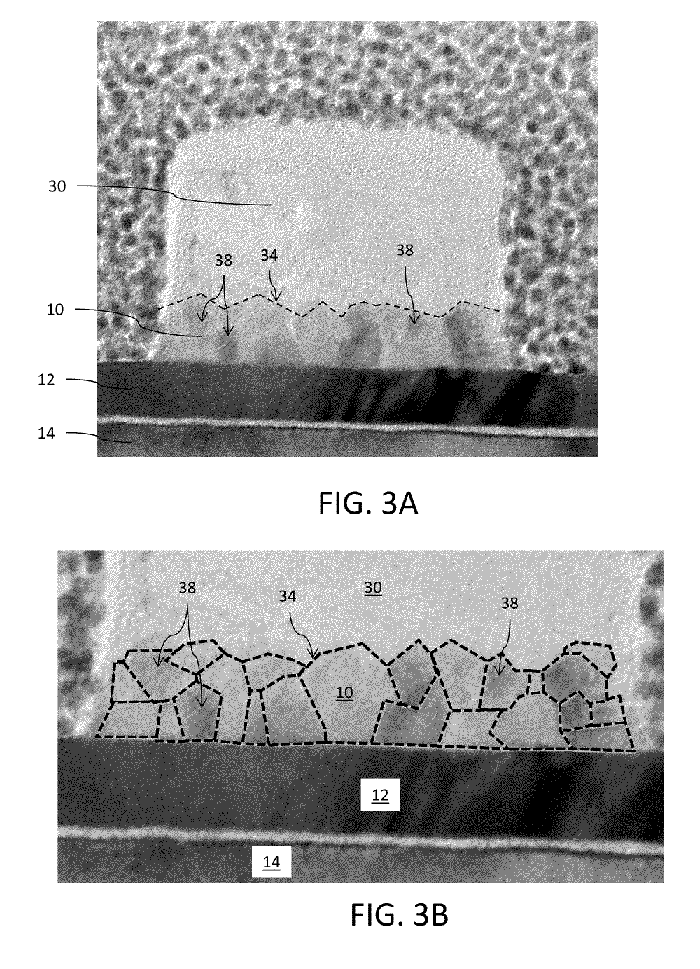

FIG. 3A shows a cross-sectional image of MOSFET device including a semiconductor substrate 14, high-k dielectric layer 12 and a TiN layer 10, wherein the TiN layer 10 exhibits an equiaxed micromorphology and a polysilicon gate electrode 30. The structure of the gate stack has a rough interface 34 between the TiN layer 10 and the polysilicon gate electrode 30. Furthermore, TiN layer 10 exhibits a number of grains 38 (shown in more detail in FIG. 3B) which lack a columnar structure. Indeed, the equiaxed structure is characterized by grains that have no preferred direction and whose shape yields a material possessing more isotropic electrical and mechanical properties.

While the equiaxed grain structure produced using the process taught by U.S. Pat. No. 9,691,871 provides for transistors with reduced local variability in threshold voltage, there remains room for improvement. To achieve this improvement, the Inventors propose a modification of the process taught by U.S. Pat. No. 9,691,871 that will result in the production of a metal nitride work function material which exhibits a uniaxial grain orientation. In this context, a “uniaxial grain orientation” is defined to mean that greater than 95% of the grains in the metal nitride material of the work function metal have an identical grain orientation. Indeed, in a preferred implementation, the uniaxial grain orientation achieves greater than 99% of the grains in the metal nitride material of the work function metal having an identical grain orientation. The particular grain orientation produced by the process, such as, for example, a <111> or a <200> grain orientation, can be selected by modification of the process as will be discussed herein. The uniaxial grain orientation differs significantly from the equiaxed structure where the grains have no preferred orientation direction.

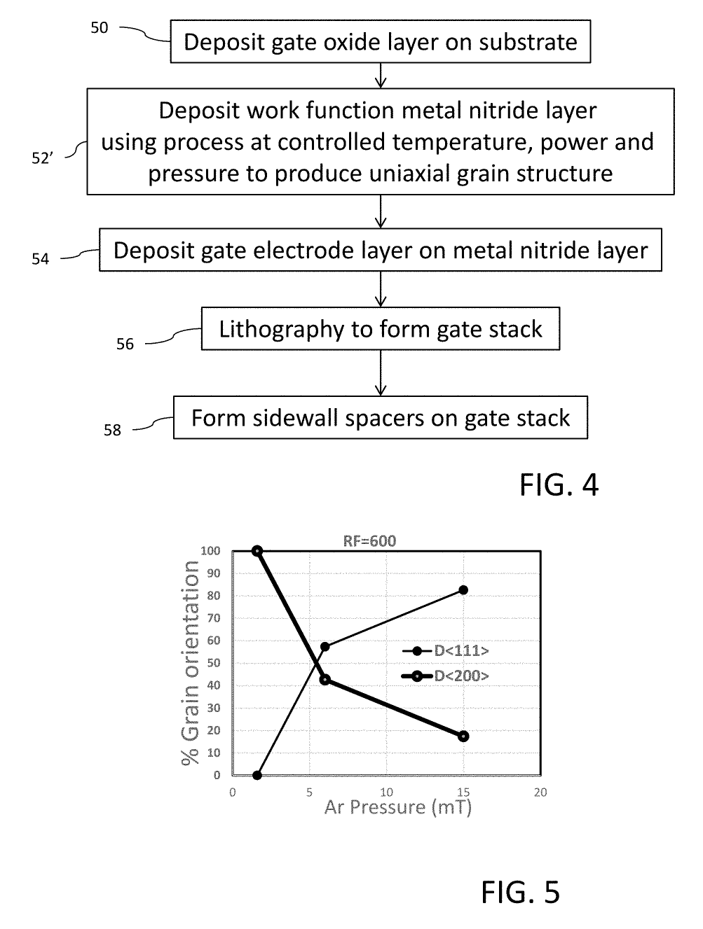

Reference is now made to FIG. 4 showing a process flow diagram for the formation of a transistor gate region. Identical steps between the processes of FIGS. 1 and 4 have same reference numbers and for sake of brevity will not be further described. The process of FIG. 4 generally differs from the process of FIG. 1 in connection with the deposition of the work function metal nitride layer (step 52 of FIG. 1 and step 52′ of FIG. 4). The process of step 52′ in FIG. 4 is tuned to produce a metal nitride work function material which exhibits a uniaxial grain orientation.

Consider first the details of the process of step 52′ for the production of a metal nitride work function material which exhibits a uniaxial <200> grain orientation which is deposited on the gate oxide layer. The work function metal nitride layer may, for example, comprise a titanium nitride (TiN) material. The deposition is made using a physical vapor deposition (PVD) process in radio frequency mode (RF-PVD). For a Gate-First integration scheme, where the work function metal nitride is deposited in planar mode and where highly uniform and continuous thin films are desirable (since work function metal thickness modulates threshold voltage of the MOSFET), the RF-PVD deposition of the work function metal nitride is performed at very low pressure that is less than or equal to 1.6 mTorr. As a result, the RF-PVD with controlled temperature and a very low pressure will produce a uniaxial grain orientation TiN film layer having a near or at 100% <200> grain orientation.

The following table provides an example of the process parameters used in RF-PVD for step 52′ (where “Test” designates a point of reference only) for the production of TiN exhibiting a uniaxial <200> grain orientation:

| | | |
|---|---|---|
| Deposition Parameter | Test | Ranges |

| | | | |
|---|---|---|---|
| Power DC (W) | 700 | 300 | 1000 |
| Power RF (W) | 600 | 400 | 1200 |
| Argon flow (sccm) | 6.67 | 1 | 10 |
| Nitrogen flow (sccm) | 15 | 2 | 20 |
| Pressure during deposition (mTorr) | 1.60 | 0.1 | <2 |
| Temperature (° C.) | 20 | −10 | 100 |

With respect to step 52′, the wafer is first degased in a dedicated chamber at a temperature no more 200° C. and for a duration preferably no more than 30 seconds to remove moisture. Then the wafer is introduced inside the RF-PVD chamber. This chamber must be equipped with a pedestal set at the appropriate temperature, and hardware to clamp the wafer on the chuck. A gas vector at the backside of the wafer must also be used for good heat exchange. After wafer clamping (for example 1 second), temperature and process pressure stabilization (for example, 7.5 mTorr during 60 seconds, using Ar 100 sccm and nitrogen 50 sccm), the plasma is turned on with only RF power (for example, 1 second using RF 300 W). Then, after increasing RF power (for example, 600 W), DC power is turned on during the appropriate time to reach the desired film thickness (for example, DC 700 W during 17 to 40 seconds). During this deposition, Ar flow is set to 6.67 sccm and nitrogen flow is set to 15 sccm to achieve a pressure of 1.6 mTorr. After that, DC power is turned off first (for example, during 0.5 second), and then finally RF power. At the end, the chamber is pumped down (for example, during at least 10 seconds).

Advantageously, the RF-PVD process as described above is performed at a low enough temperature to ensure that the nitrogen added to the gate oxide layer for adjusting the centering of the transistor device is not desorbed. Additionally, the DC/RF power is low enough to obviate concerns with causing damage to the high-K dielectric material for the gate oxide layer.

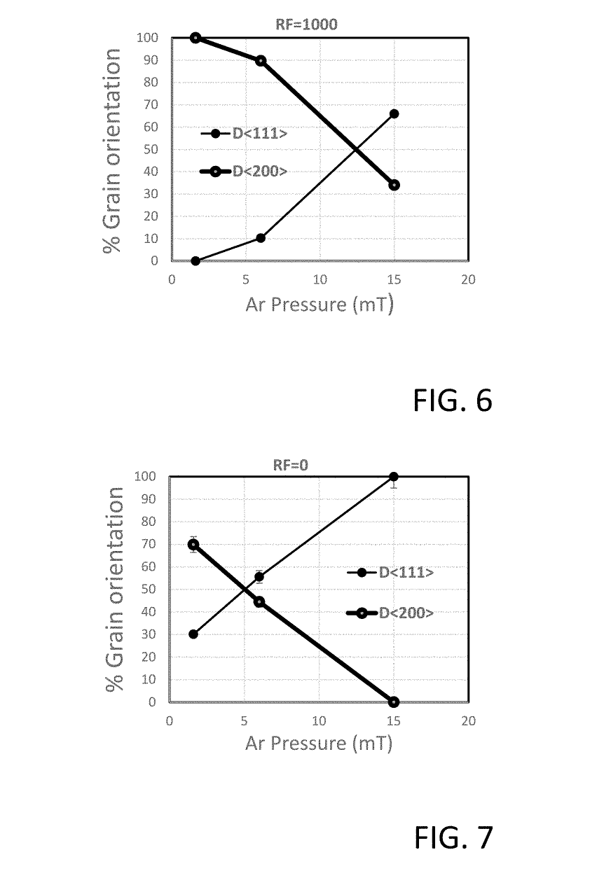

The TiN material exhibiting a uniaxial <200> grain orientation produced by use of these process parameters exhibits an average grain size of about 21 nm. FIG. 5 shows a graph of the effect of varying pressure with an RF power of 600 W using the process parameters of the above Table. FIG. 6 shows a graph of the effect of varying pressure with an RF power of 1000 W using the process parameters of the above Table. It will be noted that reducing the pressure to less than or equal to 1.6 mTorr will produce TiN material grains exhibiting substantially only the <200> grain orientation (with no material exhibiting the <111> grain orientation), and the results are consistent over a range of RF power settings from at least 600 W to 1000 W. This data is obtained using an X-ray diffraction analysis “out of plane” on three samples formed at three different process pressures to provide information relating to percent of grains present in each grain orientation.

Consider next the details of the process of step 52′ for the production of a metal nitride work function material which exhibits a uniaxial <111> grain orientation which is deposited on the gate oxide layer. The work function metal nitride layer may, for example, comprise a titanium nitride (TiN) material. The deposition is made using a physical vapor deposition (PVD) process in radio frequency mode (RF-PVD). For a Gate-First integration scheme, where the work function metal nitride is deposited in planar mode and where highly uniform and continuous thin films are desirable (since work function metal thickness modulates threshold voltage of the MOSFET), the RF-PVD deposition of the work function metal nitride is performed at a relatively higher pressure that is greater than or equal to 15 mTorr and with no RF power applied during the deposition step. As a result, the RF-PVD with controlled temperature and a relatively high pressure and no RF power during deposition will produce a uniaxial TiN film layer having a near or at 100% <111> grain orientation. In support of this process, the ‘mid-position gate valve’ of the RF-PVD chamber as shown in FIG. 2 is controlled by the process technician to throttle the cryopump and achieve the desired higher process pressure without using too high gas flow conditions and without decreasing the cryopump pumping capacity.

The following table provides another example of the process parameters used in RF-PVD for step 52′ (where “Test” designates a point of reference only) for the production of TiN exhibiting a uniaxial <111> grain orientation:

| | | |
|---|---|---|
| Deposition Parameter | Test | Ranges |

| | | | |
|---|---|---|---|
| Power DC (W) | 700 | 300 | 1000 |
| Power RF (W) | 0 | 0 | 100 |
| Argon flow (sccm) | 20 | 5 | 50 |
| Nitrogen flow (sccm) | 45 | 15 | 100 |
| Pressure during deposition (mTorr) | 15 | 13 | 50 |
| Temperature (° C.) | 20 | −10 | 100 |

With respect to step 52′, the wafer is first degased in a dedicated chamber at a temperature no more 200° C. and for a duration preferably no more than 30 seconds to remove moisture. Then the wafer is introduced inside the RF-PVD chamber. This chamber must be equipped with a pedestal set at the appropriate temperature, and hardware to clamp the wafer on the chuck. A gas vector at the backside of the wafer must also be used for good heat exchange. After wafer clamping (for example 1 second), temperature and process pressure stabilization (for example, 7.5 mTorr during 60 seconds, using Ar 100 sccm and nitrogen 50 sccm), the plasma is turned on with only RF power (for example, 1 second using RF 300 W. Then, the RF power is completely turned off (i.e., RF OW) and DC power is turned on during deposition for the appropriate time to reach the desired film thickness (for example, DC 700 W during 500 to 1000 seconds). During this deposition, Ar flow is set to 20 sccm and nitrogen flow is set to 45 sccm to achieve a pressure f 15 mTorr. After that, DC power is turned off (for example, during 0.5 second). At the end, the chamber is pumped down (for example, during at least 10 seconds).

Advantageously, the RF-PVD process as described above is performed at a low enough temperature to ensure that the nitrogen added to the gate oxide layer for adjusting the centering of the transistor device is not desorbed. Additionally, the DC/RF power is low enough to obviate concerns with causing damage to the high-K dielectric material for the gate oxide layer.

The TiN material exhibiting a uniaxial <111> grain orientation produced by use of these process parameters exhibits an average grain size of about 9 nm. FIG. 7 shows a graph of the effect of varying pressure with an RF power of 0 W using the process parameters of the above Table. It will be noted that increasing the pressure to greater than or equal to 15 mTorr will produce TiN material grains exhibiting only the <111> grain orientation (with no material exhibiting the <200> grain orientation). This data is obtained using an X-ray diffraction analysis “out of plane” on three samples formed at three different process pressures to provide information relating to percent of grains present in each grain orientation.

The concept of a uniaxial grain film is applicable to all gate materials: pure materials (for example Al, Si, W, Ni, Co, Ti, Ta, Ru), metal nitrides (for example TiN, TaN, WN, AIN), metal carbides (for example TaC), and even to conductive metal oxides (for example RuO and InSnO). RF-PVD allows the deposition of all these types of materials, with similar values of the process parameters.

To summarize, it is noted that local variability of the grain size of the gate work function metal as well as its crystal orientation induce variable work function and local variability of the threshold voltage of MOS transistors. The Inventors have discovered that deposition of the metal nitride for the work function metal of the transistor gate using RF-PVD can yield uniaxial grains (see, FIG. 4, step 52′). This process is achieved by maintaining a low process temperature but with controlling the deposition pressure and/or RF power as described above. This low temperature process is compatible with the requirement to maintain nitrogen content in the gate oxide layer and not damage the gate oxide.

Although illustrated herein in the context of a planar MOSFET device, it will be understood that the uniaxial grain orientation work function metal nitride layer may be used in any suitable integrated circuit device including all types of FET devices which utilize work function metal layers in the gate stack (for example, including, finFET devices).

The process disclosed herein for producing the work function metal layer which exhibits a uniaxial grain orientation has the following advantages:

a) keeping a low temperature (i.e., about 20° C.) process solution in order to avoid Nitrogen desorption from thee High-K dielectrics used for the gate oxide;

b) keeping a limited deposition rate (i.e., 1.9 Å/sec) in order to limit damage on the High-K dielectrics by use of a 600-1000 W RF power range that provides for a low pressure option; and

c) uses RF-PVD to keep low non-uniformity that is required for metal gate (non-uniformity (NU) thickness 1.7% and sheet resistance (Rs) 2.4%).

The foregoing description has provided by way of exemplary and non-limiting examples a full and informative description of one or more exemplary embodiments of this invention. However, various modifications and adaptations may become apparent to those skilled in the relevant arts in view of the foregoing description, when read in conjunction with the accompanying drawings and the appended claims.

However, all such and similar modifications of the teachings of this invention will still fall within the scope of this invention as defined in the appended claims.

What is claimed is:

1. A method, comprising:
depositing a gate oxide layer over a substrate;
depositing a work function metal nitride layer over the gate oxide layer;
depositing a gate electrode layer over the work function metal nitride layer;
wherein depositing the work function metal nitride layer comprises using a deposition process that produces the work function metal nitride layer exhibiting a uniaxial grain orientation.

2. The method of claim 1, wherein said deposition process comprises physical vapor deposition in radio frequency mode (RF-PVD).

3. The method of claim 2, wherein the RF-PVD is performed at a temperature of about 20° C. and a pressure of that is less than or equal to 1.6 mTorr.

4. The method of claim 3, wherein the RF-PVD is performed at an RF power of between 600 W and 1000 W.

5. The method of claim 4, wherein the RF-PVD is performed at a DC power of about 700 W.

6. The method of claim 4, wherein the RF-PVD is performed with an Argon flow of 6-7 sccm and a Nitrogen flow of about 15 sccm during the deposition of the work function metal nitride layer.

7. The method of claim 4, wherein the uniaxial grain orientation is a <200> grain orientation.

8. The method of claim 2, wherein the RF-PVD is performed at a temperature of about 20° C. and a pressure of that is greater than or equal to 15 mTorr.

9. The method of claim 8, wherein the RF-PVD is performed at an RF power of 0 W.

10. The method of claim 9, wherein the RF-PVD is performed at a DC power of about 700 W.

11. The method of claim 9, wherein the RF-PVD is performed with an Argon flow of about 20 sccm and a Nitrogen flow of about 45 sccm during the deposition of the work function metal nitride layer.

12. The method of claim 9, wherein the uniaxial grain orientation is a <111> grain orientation.

13. The method of claim 1, wherein the work function metal nitride layer is made of a titanium nitride material.

14. The method of claim 13, wherein the gate electrode layer is made of a polysilicon material.

15. A method, comprising:
depositing a gate oxide layer over a substrate;
depositing a work function metal nitride layer over the gate oxide layer;
depositing a gate electrode layer over the work function metal nitride layer;
wherein depositing the work function metal nitride layer comprises using a deposition process having a deposition pressure less than or equal to 1.6 mTorr that produces the work function metal nitride layer where greater than 95% of the metal nitride grains exhibit a <200> grain orientation.

16. The method of claim 15, wherein greater than 99% of the metal nitride grains exhibit the <200> grain orientation.

17. The method of claim 15, wherein said deposition process comprises physical vapor deposition in radio frequency mode (RF-PVD) performed at a temperature of about 20° C., and an RF power of between 600 W and 1000 W.

18. The method of claim 15, wherein the work function metal nitride layer is made of a titanium nitride material.

19. The method of claim 18, wherein the gate electrode layer is made of a polysilicon material.

20. The method of claim 15, wherein the deposition process comprises setting an Argon flow of 6-7 sccm and a Nitrogen flow of about 15 sccm during the deposition so as to produce the deposition pressure that is less than or equal to 1.6 mTorr.

21. A method, comprising:
depositing a gate oxide layer over a substrate;
depositing a work function metal nitride layer over the gate oxide layer;
depositing a gate electrode layer over the work function metal nitride layer;
wherein depositing the work function metal nitride layer comprises using a deposition process having a deposition pressure greater than or equal to 15 mTorr that produces the work function metal nitride layer where greater than 95% of the metal nitride grains exhibit a <111> grain orientation.

22. The method of claim 21, wherein greater than 99% of the metal nitride grains exhibit the <111> grain orientation.

23. The method of claim 21, wherein said deposition process comprises physical vapor deposition in radio frequency mode (RF-PVD) performed at a temperature of about 20° C., and an RF power of 0 W.

24. The method of claim 21, wherein the work function metal nitride layer is made of a titanium nitride material.

25. The method of claim 24, wherein the gate electrode layer is made of a polysilicon material.

26. The method of claim 24, wherein the deposition process comprises setting an Argon flow of 20 sccm and a Nitrogen flow of about 45 sccm during the deposition so as to produce the deposition pressure that is greater than or equal to 15 mTorr.

27. The method of claim 26, further comprising controlling a gate valve between a deposition chamber and a cryo pump to a mid-opening position so as to control the deposition pressure to be greater than or equal to 15 mTorr.

28. An integrated circuit, comprising:
a substrate;
a gate oxide layer deposited over the substrate;
a work function metal nitride layer deposited over the gate oxide layer;
a gate electrode layer deposited over the work function metal nitride layer;
wherein greater than 95% of metal nitride grains of the work function metal nitride layer exhibit a <200> grain orientation.

29. The integrated circuit of claim 28, wherein the work function metal nitride layer is made of a titanium nitride material.

30. An integrated circuit, comprising:
a substrate;
a gate oxide layer deposited over the substrate;
a work function metal nitride layer deposited over the gate oxide layer;
a gate electrode layer deposited over the work function metal nitride layer;
wherein greater than 95% of metal nitride grains of the work function metal nitride layer exhibit a <111> grain orientation.

31. The integrated circuit of claim 30, wherein the work function metal nitride layer is made of a titanium nitride material.
